(19) United States
(12) Patent Application Publication
(10) Pub. No.: US 2025/0336676 A1
(43) Pub. Date: Oct. 30, 2025

(54) METHOD OF MANUFACTURING SEMICONDUCTOR DEVICE

(71) Applicant: DENSO CORPORATION, Kariya-city (JP)

(72) Inventor: Masakazu WATANABE, Kariya-city (JP)

(21) Appl. No.: 19/261,482

(22) Filed: Jul. 7, 2025

Related U.S. Application Data
(63) Continuation of application No. PCT/JP2023/037737, filed on Oct. 18, 2023.

(30) Foreign Application Priority Data
Jan. 10, 2023 (JP) 2023-001709

(51) Int. Cl. H01L 21/04

(52) U.S. Cl. CPC H01L 21/0465

(57) ABSTRACT

A method of manufacturing a semiconductor device includes: implanting a first conductivity type impurity into a SiC substrate; and implanting a second conductivity type impurity into the SiC substrate. A concentration distribution of the first conductivity type impurity has a reduction region, in which the concentration of first conductivity type impurity continuously decreases as moving away from a first peak value. A concentration distribution of the second conductivity type impurity has a second peak value. The second peak value overlaps with a specific region within the reduction region that has a first conductivity type impurity concentration that is 10% or more of the first peak value. The position of the first peak value is the first conductivity type region. At least a part of the specific region is the second conductivity type region.

### CROSS REFERENCE TO RELATED APPLICATIONS

The present application is a continuation application of International Patent Application No. PCT/JP2023/037737 filed on Oct. 18, 2023, which designated the U.S. and claims the benefit of priority from Japanese Patent Application No. 2023-001709 filed on Jan. 10, 2023. The entire disclosures of all of the above applications are incorporated herein by reference.

### TECHNICAL FIELD

The present disclosure relates to a method of manufacturing a semiconductor device.

### BACKGROUND

There is a technique for ion-implanting impurities into a SiC substrate, which is a semiconductor substrate made of silicon carbide.

### SUMMARY

A method of manufacturing a semiconductor device includes: implanting a first conductivity type impurity into a SiC substrate; and implanting a second conductivity type impurity into the SiC substrate. The impurities are implanted to satisfy the following conditions: a concentration distribution of the first conductivity type impurity implanted in a thickness direction of the SiC substrate has a first peak value that is a maximum value and a reduction region in which a concentration of the first conductivity type impurity continuously decreases with increasing distance from a position of the first peak value; a concentration distribution of the second conductivity type impurity implanted in the thickness direction of the SiC substrate has a second peak value that is a maximum value; a position of the second peak value overlaps with a specific region of the decrease region having a first conductivity type impurity concentration that is 10% or more of the first peak value; a position of the first peak value is a first conductivity type region; and at least a part of the specific region is a second conductivity type region.

### BRIEF DESCRIPTION OF DRAWINGS

FIG. 1 is an explanatory diagram illustrating a first step in a first embodiment.

FIG. 2 shows a concentration distribution of a p-type impurity implanted in the first step according to the first embodiment, in which (a) is a cross-sectional view and (b) is a graph at a depth along a line A-A.

FIG. 3 is an explanatory diagram illustrating a first process of a second step in the first embodiment.

FIG. 4 shows an effective p-type impurity concentration distribution after the second step is performed in the first embodiment, in which (a) is a cross-sectional view and (b) is a graph at a depth along a line A-A.

FIG. 5 is an explanatory diagram illustrating a second process of the second step in the first embodiment.

FIG. 6 is a cross-sectional view of a MOSFET manufactured by the manufacturing method of the first embodiment.

FIG. 7 is an explanatory diagram illustrating a first step in a second embodiment.

FIG. 8 shows a concentration distribution of a p-type impurity implanted in the first step according to the second embodiment, in which (a) is a cross-sectional view, and (b) is a graph at a depth along a line A-A.

FIG. 9 is an explanatory diagram illustrating a second step in the second embodiment.

FIG. 10 shows an effective p-type impurity concentration distribution after the second step is performed in the second embodiment, in which (a) is a cross-sectional view and (b) is a graph at a depth along a line A-A.

FIG. 11 is a cross-sectional view of a MOSFET manufactured by the manufacturing method of the second embodiment.

FIG. 12 is an explanatory diagram illustrating a manufacturing step of the MOSFET of FIG. 11.

FIG. 13 is an explanatory diagram illustrating a manufacturing step of the MOSFET of FIG. 11.

### DESCRIPTION OF EMBODIMENTS

When ions are implanted into a SiC substrate, the implanted impurities are diffused over a wide range. For this reason, it is difficult to form the impurity implanted region with high precision. In a SiC substrate, thermal diffusion of impurities is unlikely to occur during activation annealing, so forming an impurity implanted region with high accuracy during ion implantation leads to improved accuracy in forming a p-type or n-type region. This specification proposes a semiconductor device to form an impurity implanted region with high precision when implanting ions into a SiC substrate.

A method of manufacturing a semiconductor device includes: a first step of implanting a first conductivity type impurity into a SiC substrate; and a second step of implanting a second conductivity type impurity into the SiC substrate. The first step and the second step are performed to satisfy the following conditions: a concentration distribution of the first conductivity type impurity implanted in the first step in a thickness direction of the SiC substrate has a first peak value that is a maximum value and a reduction region in which a concentration of the first conductivity type impurity continuously decreases with increasing distance from a position of the first peak value; a concentration distribution of the second conductivity type impurity implanted in the second step in the thickness direction of the SiC substrate has a second peak value that is a maximum value; a position of the second peak value overlaps with a specific region of the decrease region having a first conductivity type impurity concentration that is 10% or more of the first peak value; a position of the first peak value is a first conductivity type region; and at least a part of the specific region is a second conductivity type region.

Either the first conductivity type region or the second conductivity type region is p-type, and the other is n-type. That is, when the first conductivity type region is p-type, the second conductivity type region is n-type. When the first conductivity type region is n-type, the second conductivity type region is p-type.

The first peak value, the second peak value, and the reduction region are identified based on a distribution graph from which noise occurring during measurement of the impurity concentration has been removed.

Either the first step or the second step may be carried out first.

In the manufacturing method, the concentration distribution of the first conductivity type impurity implanted in the first step has: the first peak value which is a maximum value; and the reduction region in which the concentration of the first conductivity type impurity continuously decreases with increasing distance from the position of the first peak value. The reduction region is generated by variations in implantation depth in the region where the impurities are implanted during ion implantation. The position of the second peak value of the concentration distribution of the second conductivity type impurity implanted in the second step overlaps with a specific region of the reduction region having a first conductivity type impurity concentration that is 10% or more of the first peak value. At least a part of the specific region becomes a second conductivity type region. Therefore, the first conductivity type region can be formed in a limited area around the position of the first peak value. In this manner, according to this manufacturing method, the first conductivity type region can be formed with high precision.

In one example of a manufacturing method, a position of the second peak value may overlap with the specific region that is located shallower than the position of the first peak value.

In one example of the manufacturing method, a position of the second peak value may overlap with the specific region that is located deeper than the position of the first peak value.

Note that “shallow” means that the implantation distance of the impurity in the first step is short, and “deep” means that the implantation distance of the impurity in the first step is long.

The manufacturing method may further include a step of forming a mask having an opening on a surface of the SiC substrate. In this case, in the first step, a first conductivity type impurity may be implanted into the SiC substrate through the mask, and in the second step, a second conductivity type impurity may be implanted into the SiC substrate through the mask.

In the case of implantation through the mask, the first conductivity type impurity is likely to diffuse laterally (that is, in a direction parallel to the surface of the semiconductor substrate) in the first step. By carrying out the second step using the same mask as in the first step, the second conductivity type impurity can be diffused laterally in the second step. This makes it possible to limit the area in which the first conductivity type region is formed in the lateral direction as well.

In one example of the manufacturing method, the opening may have a width of 3.5 μm or less.

In one example of the manufacturing method, a semiconductor device manufactured by the manufacturing method may have an element region and a p-type guard ring extending to surround a periphery of the element region. In this case, the first conductivity type region formed at the position of the first peak value may be the guard ring.

In one example of the manufacturing method, a semiconductor device manufactured by the manufacturing method may have a superjunction structure in which p-type layers and n-type layers are laterally alternately arranged in the drift region. The first conductivity type region formed at the position of the first peak value may be the p-type layer of the superjunction structure.

### First Embodiment

A method of manufacturing a semiconductor device of a first embodiment includes a mask formation step, a first step of implanting p-type impurities into the SiC substrate, and a second step of implanting n-type impurities into the SiC substrate.

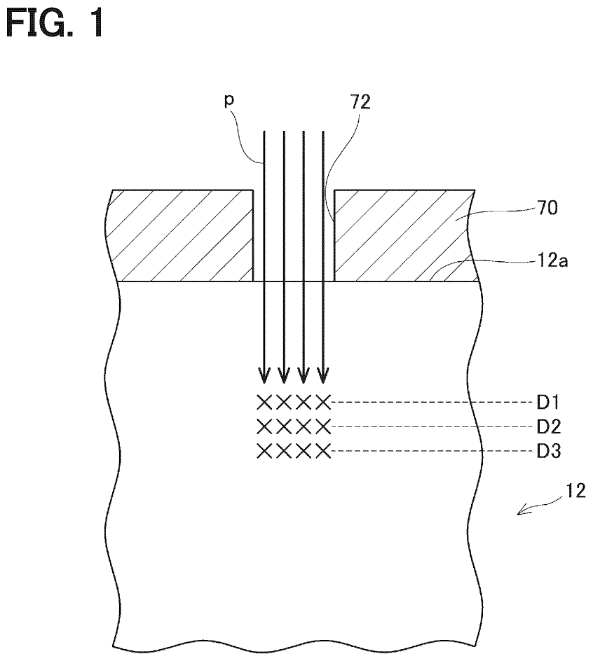

In the mask formation step, as shown in FIG. 1, a mask 70 is formed on the upper surface 12a of the SiC substrate 12. The mask 70 has an opening 72. The SiC substrate 12 is made of n-type SiC. The n-type impurity concentration of the SiC substrate 12 is, for example, about 1×10¹⁵ cm⁻³.

After the mask formation step, the first step is carried out. In the first step, as shown in FIG. 1, p-type impurities are ion-implanted into the SiC substrate 12 through the mask 70. Therefore, the p-type impurity is implanted into the SiC substrate 12 from the upper surface 12a within the opening 72. The p-type impurities are implanted into the SiC substrate 12 along the thickness direction. The p-type impurity is implanted multiple times while changing the acceleration energy. As a result, the p-type impurities are implanted at approximately the same concentration into each of the depths D1, D2, D3.

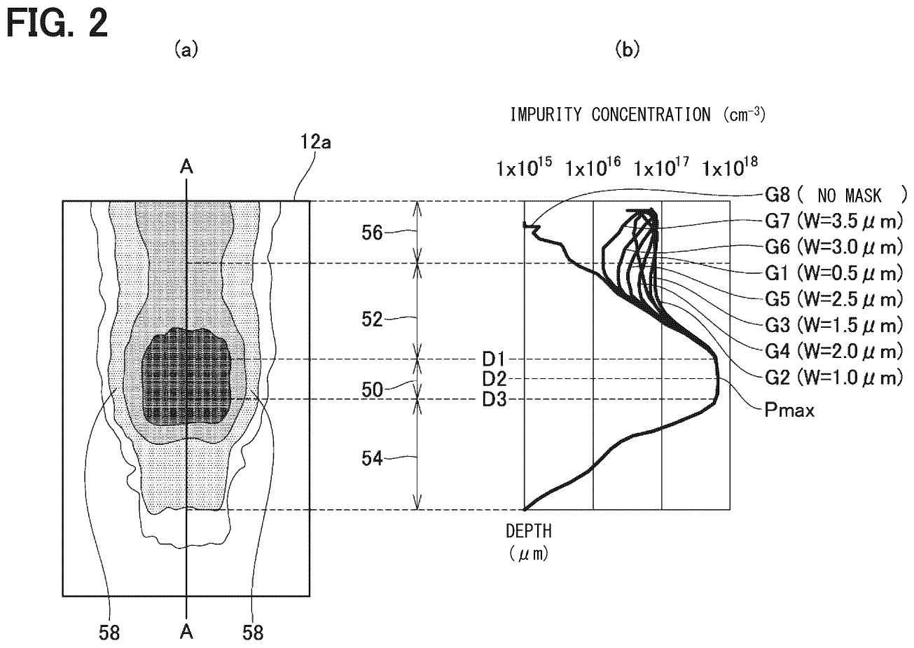

FIG. 2 shows the concentration distribution of the p-type impurity after the first step is performed. In FIG. 2, (a) shows the same cross-section as FIG. 1, and the density of the hatched areas indicates the concentration of the p-type impurity. In FIG. 2, (b) shows the concentration distribution of the p-type impurity at the depth along the line A-A in (a) of FIG. 2. Graphs G1 to G7 in (b) of FIG. 2 show the results of carrying out the first step while changing the width W of the opening 72. Graph G8 in (b) of FIG. 2 shows the result of performing the first step without the mask 70 for reference.

As described above, in the first step, since the p-type impurities are implanted to the plural depths D1, D2, D3, the p-type impurity concentration is distributed at a high value (e.g., 8×10¹⁷ cm⁻³) and is almost constant within the depth range including the depths D1, D2, D3. Hereinafter, the range in which the p-type impurity concentration is distributed at a substantially constant high value will be referred to as a main region 50. A peak value Pmax of the p-type impurity is formed in the main region 50. A reduction region 52 is defined above the main region 50, and a reduction region 54 is defined below the main region 50. In the reduction region 52, 54, the p-type impurity concentration continuously decreases with increasing distance from the main region 50. In (b) of FIG. 2, the reduction region 52 of the graph G7 is shown as an example. The reduction region 52, 54 is formed due to variations in the implantation depth of the p-type impurity in the first step. The reduction region 52 is formed above the main region 50 (i.e., on the shallower side in the implantation direction of the p-type impurity). In the reduction region 52, the p-type impurity concentration continuously decreases toward the upper side. The reduction region 54 is formed below the main region 50 (i.e., on the deeper side in the implantation direction of the p-type impurity). In the reduction region 54, the p-type impurity concentration continuously decreases toward the lower side.

Moreover, an increase region 56 is defined above the reduction region 52. The increase region 56 has a higher p-type impurity concentration than the upper end of the reduction region 52. The increase region 56 is formed by the p-type impurities scattered and reflected by the mask 70. Therefore, as shown by the graph G8 in (b) of FIG. 2, in the absence of mask 70, the increase region 56 is not formed. Furthermore, as shown by the graphs G1 to G7 in (b) of FIG. 2, there is a tendency that the p-type impurity concentration in the increase region 56 increases as the width W of the opening 72 decreases. This is because the smaller the width W of the opening 72, the more the p-type impurity is scattered and reflected by the mask 70.

As shown in (a) of FIG. 2, a peripheral region 58 is formed at a position adjacent to the main region 50 in the lateral direction perpendicular to the implantation direction. The p-type impurities are distributed at a low concentration in the peripheral region 58. The peripheral region 58 is defined by the p-type impurities scattered and reflected by the mask 70.

As described above, in the first step, the p-type impurity is implanted not only into the main region 50, which is the target of implantation of the p-type impurity, but also into the reduction region 52, the reduction region 54, the increase region 56, and the peripheral region 58 surrounding the main region 50.

After the first step, the second step is carried out. In the second step, n-type impurity ions are implanted into the SiC substrate 12 through the mask 70. Therefore, the n-type impurity is implanted into the SiC substrate 12 from the upper surface 12a through the opening 72. The n-type impurities are implanted into the SiC substrate 12 along the thickness direction. The implantation depth and implantation concentration of the n-type impurity in the second step are set in accordance with the p-type impurity concentration distribution formed in the first step. In the following, the second step will be described taking as an example a case where p-type impurities are implanted in the first step as shown by the graph G7 of (b) in FIG. 2. The second step includes a first process for implanting n-type impurities into the upper side of the main region 50 and a second process for implanting n-type impurities into the lower side of the main region 50.

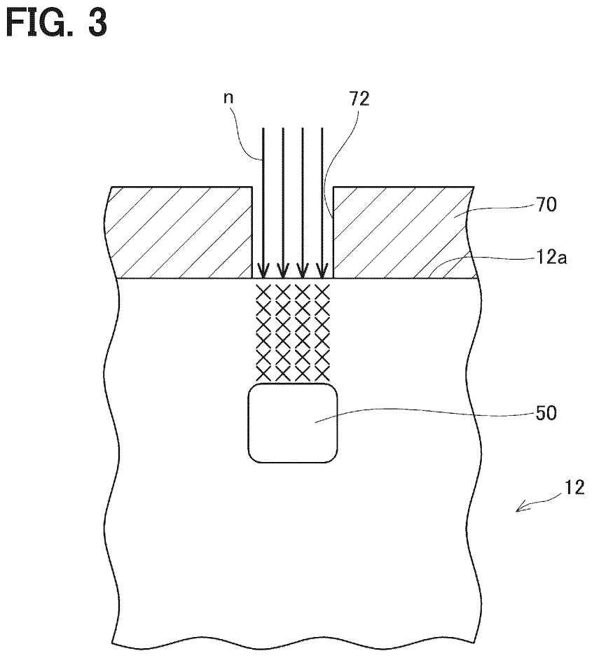

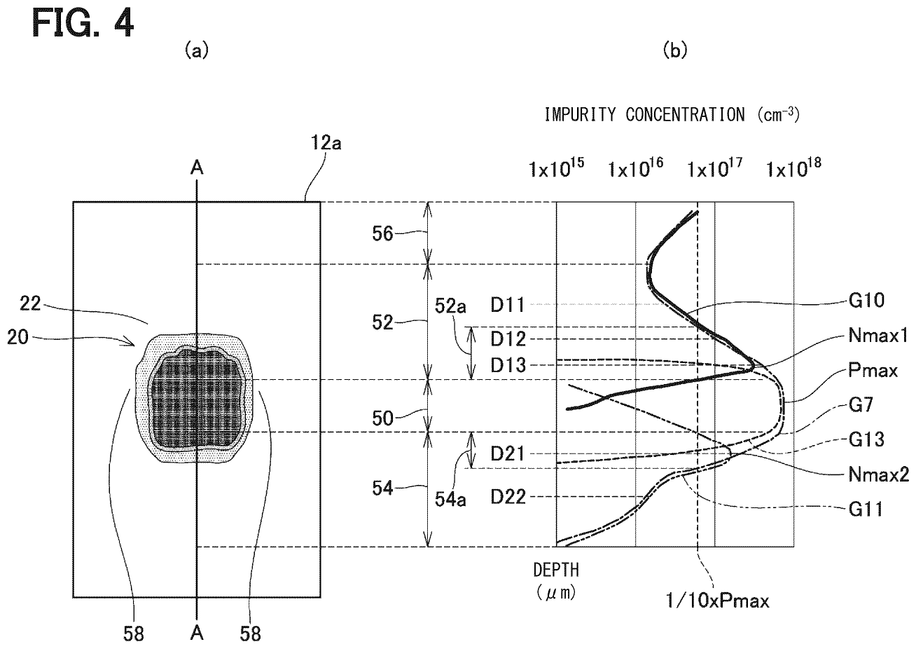

In the first process, as shown in FIG. 3, n-type impurities are implanted multiple times above the main region 50 while changing the acceleration energy. This results in implantation of n-type impurities to multiple depths in the region above the main region 50. In FIG. 4, (b) shows a graph G10 of the concentration distribution of the n-type impurity implanted into the SiC substrate 12 in the first process, superimposed on the graph G7. Moreover, a region 52a in (b) of FIG. 4, in the reduction region 52, has a p-type impurity concentration higher than 10% of the peak value Pmax. In the first process, n-type impurities are implanted at least once to a depth within the region 52a. In the example shown in (b) of FIG. 4, the n-type impurities are implanted into the reduction region 52 at depths D11, D12, D13, including the depths D12, D13 of the region 52a. Among the depths D11 to D13, the closer to the main region 50 the depth is, the higher the concentration of the n-type impurity is implanted. That is, the n-type impurity is implanted at the highest concentration at the depth D13 closest to the main region 50, and at the lowest concentration at the depth D11 farthest from the main region 50. Therefore, in the reduction region 52, a peak value Nmax1 of the n-type impurity is formed at the depth D13 in the region 52a. The n-type impurities are also implanted at multiple depths within the increase region 56. The n-type impurities are implanted so that the n-type impurity concentration is higher than the p-type impurity concentration in the range above the depth D13.

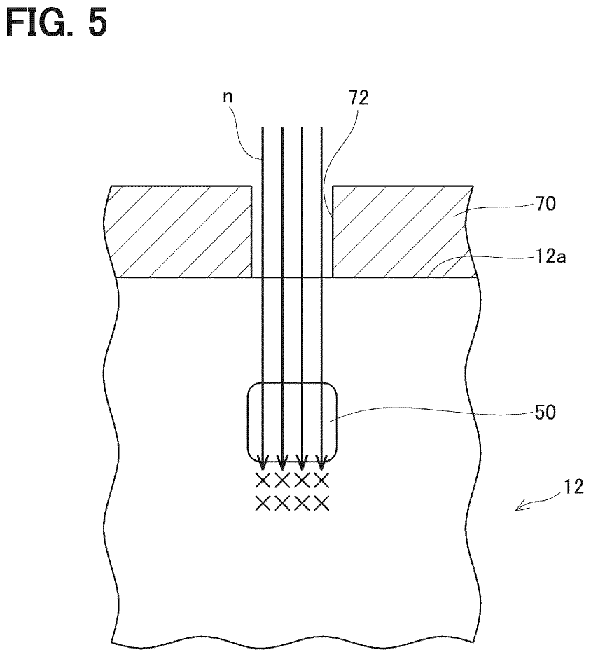

In the second process, as shown in FIG. 5, n-type impurities are implanted multiple times below the main region 50 while changing the acceleration energy. This results in implantation of n-type impurities to multiple depths in the region below the main region 50. In FIG. 4, (b) shows a graph G11 of the concentration distribution of the n-type impurity implanted into the SiC substrate 12 in the second process, superimposed on the graph G7. Moreover, a region 54a in (b) of FIG. 4, in the reduction region 54, has a p-type impurity concentration higher than 10% of the peak value Pmax. In the second process, n-type impurities are implanted at least once to a depth within region 54a. In (b) of FIG. 4, n-type impurities are implanted into the reduction region 54 at depths D21, D22 including the depth D21 of the region 54a. The closer to the main region 50 the depth is, the higher the concentration of n-type impurities is implanted at the depths D21, D22. That is, the n-type impurity is implanted at a higher concentration at the depth D21 than at the depth D22. Therefore, in the reduction region 54, a peak value Nmax2 of the n-type impurity is formed at the depth D21. The n-type impurity is implanted so that the n-type impurity concentration is higher than the p-type impurity concentration in the range below the depth D21. Furthermore, when the n-type impurity is implanted in the second process, the n-type impurity is scattered and reflected by the mask 70. The n-type impurities scattered and reflected by the mask 70 are implanted into the peripheral region 58.

In the second step, n-type impurities are implanted into the reduction region 52, the reduction region 54, the increase region 56, and the peripheral region 58. A graph G13 in (b) of FIG. 4 shows an effective p-type impurity concentration obtained by subtracting the n-type impurity concentration from the p-type impurity concentration. That is, the graph G13 shows the distribution of values obtained by subtracting the value of graphs G10 and G11 from the value of graph G7. As shown in (b) of FIG. 4, by implanting n-type impurities into the reduction region 52, the reduction region 54, and the increase region 56, the effective p-type impurity concentration in these regions becomes low. In FIG. 4, (a) shows the distribution of the effective p-type impurity concentration in the same cross-section as FIG. 5. As shown in (a) of FIG. 4, by implanting n-type impurities into the peripheral region 58, the effective p-type impurity concentration in the peripheral region 58 becomes lower. In the reduction region 52, the reduction region 54, the increase region 56 and the peripheral region 58, except in the vicinity of the main region 50, the n-type impurity concentration is higher than the p-type impurity concentration. Therefore, the effective p-type impurity concentration in the main region 50 and its vicinity has a positive value, and the effective p-type impurity concentration in other regions has a negative value.

Next, the SiC substrate 12 is annealed. This activates the p-type impurities and n-type impurities implanted into the SiC substrate 12. A region with a positive effective p-type impurity concentration becomes a p-type region 20. A region with a negative effective p-type impurity concentration (where the n-type impurity concentration is higher than the p-type impurity concentration) becomes an n-type region 22. That is, the p-type region 20 is formed in the hatched region in (a) of FIG. 4, and the n-type region 22 remains in the non-hatched region in (a) of FIG. 4. As described above, since the effective p-type impurity concentration is a positive value in the main region 50 and its vicinity, a p-type region is formed in the main region 50 and its vicinity. Since at least a part of the region 52a, 54a adjacent to the main region 50 is an n-type region, the area in which the p-type region is formed can be narrowed. In this manner, according to this manufacturing method, the p-type region 20 can be formed in a region narrower than the region into which the p-type impurity is implanted in the first step.

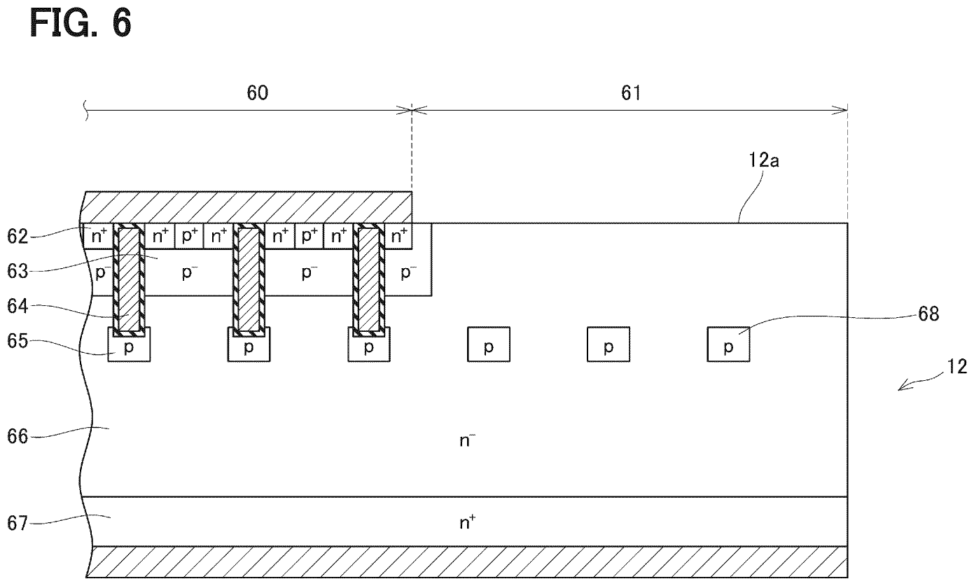

FIG. 6 shows a metal-oxide-semiconductor field effect transistor (MOSFET) as a specific example of a semiconductor device manufactured by the manufacturing method of the first embodiment. The SiC substrate 12 has an element region 60 and a peripheral region 61. Within the element region 60, a MOSFET structure is formed having an n-type source region 62, a p-type body region 63, a trench gate electrode 64, a bottom p-type region 65, an n-type drift region 66, and an n-type drain region 67. The trench gate electrode 64 is a gate electrode disposed in a trench, and is insulated from the SiC substrate 12 by a gate insulating film. The bottom p-type region 65 is in contact with the bottom surface of the trench. The peripheral region 61 is provided around the element region 60. The drift region 66 is distributed in the peripheral region 61. Plural p-type guard rings 68 are provided in the peripheral region 61. Each of the guard rings 68 is provided inside the drift region 66. When the SiC substrate 12 is viewed from the upper side, each of the guard rings 68 has a rectangular ring shape that surrounds the element region 60. Each guard ring 68 is disposed at the same depth as the bottom p-type region 65. Each guard ring 68 is formed after the element region 60 is formed. In the process of forming the guard ring 68, the mask 70 is formed on the upper surface 12a of the SiC substrate 12, and the first step (i.e., implantation of p-type impurities) and the second step (i.e., implantation of n-type impurities) can be performed through the mask 70. According to this method, the small guard ring 68 can be formed, and the MOSFET can be made smaller.

In the first embodiment, the n-type impurity is implanted into both the upper and lower sides of the main region 50 in the second step. However, in the second step, the n-type impurity may be implanted into only one of the upper and lower sides of the main region 50. When n-type impurities are implanted above the main region 50 through the mask 70, the reduction region 52 and the increase region 56 can be made n-type. When n-type impurities are implanted below the main region 50 through the mask 70, the reduction region 54 and the peripheral region 58 can be made n-type.

In the first embodiment, the impurity implantation in the first and second steps is carried out through the mask 70. However, the first and second impurity implants may be performed without the mask. Even with this configuration, a small p-type region can be formed by implanting an n-type impurity into the reduction region of the graph G8 in (b) of FIG. 2. However, when the p-type impurity is implanted through the mask, the p-type impurity implanted into the increase region 56 and the peripheral region 58 may become significant. As shown in (b) of FIG. 2, when the width of the opening of the mask is 3.5 μm or less, the p-type impurities implanted into the increase region 56 and the peripheral region 58 may become more pronounced. Therefore, by using the technique disclosed in this specification when the width of the mask opening is 3.5 μm or less, a greater effect in suppressing the expansion of the p-type region can be obtained.

### Second Embodiment

In the second embodiment, the mask formation step is carried out in the same manner as in the first embodiment. Thereafter, the first and second steps are carried out.

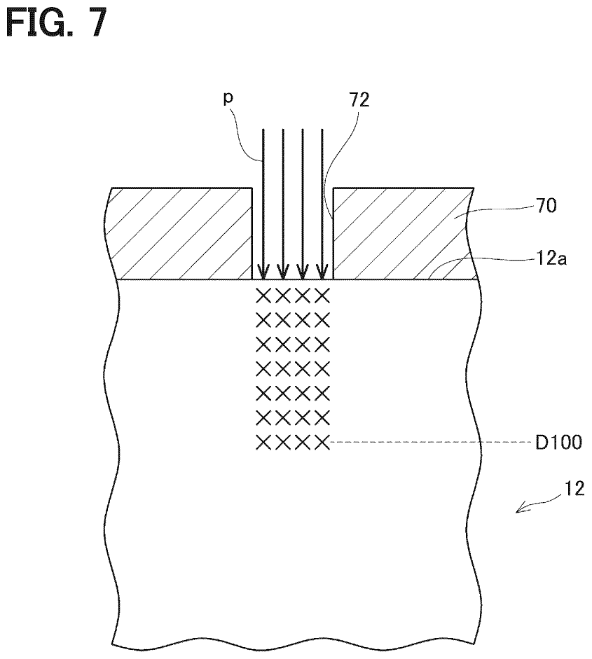

In a first step of the second embodiment, as shown in FIG. 7, p-type impurities are ion-implanted into the SiC substrate 12 through the mask 70. The p-type impurities are implanted multiple times while changing the acceleration energy. Unlike the first embodiment, p-type impurities are implanted at equal intervals into the depth range from the upper surface 12a of the SiC substrate 12 to a depth D100. The p-type impurities are implanted at approximately the same concentration to each depth.

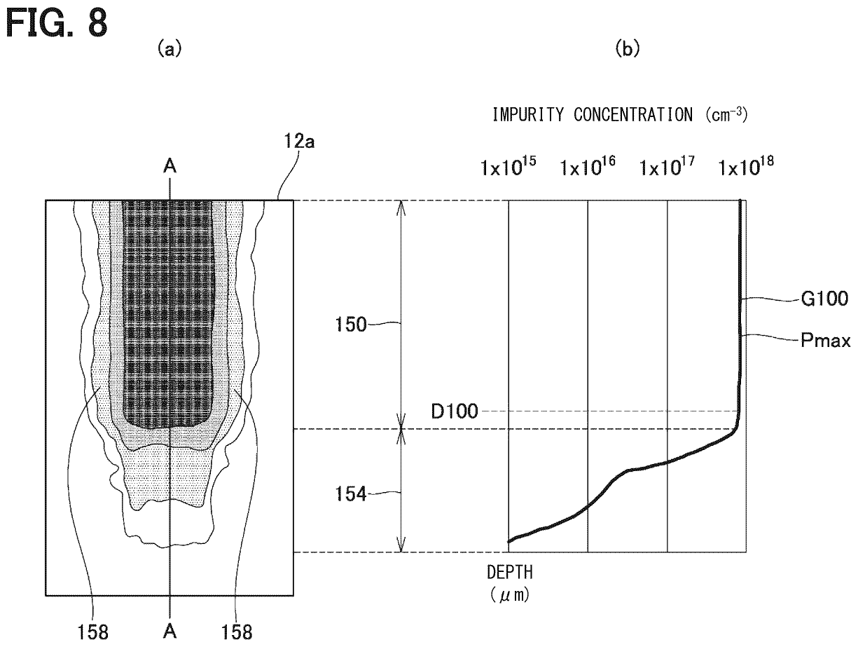

FIG. 8 shows the concentration distribution of the p-type impurity after the first step is performed. More specifically, (a) of FIG. 8 shows the same cross-section as FIG. 7, and the density of the hatched areas indicates the concentration of the p-type impurity. In FIG. 8, (b) shows the concentration distribution of the p-type impurity at the position along the line A-A in (a) of FIG. 8 by a graph G100. Within the depth range from the upper surface 12a to the depth D100, the p-type impurity concentration is distributed almost uniformly at a high value (for example, 8×10¹⁷ cm⁻³). Hereinafter, the region in which the p-type impurity concentration is distributed at a substantially constant level will be referred to as a main region 150. A peak value Pmax of the p-type impurity is formed in the main region 150. A reduction region 154 is defined below the main region 150, in which the p-type impurity concentration continuously decreases with increasing distance from the main region 150. The reduction region 154 is formed due to variations in the implantation depth of the p-type impurity in the first step.

As shown in (a) of FIG. 8, a peripheral region 158 in which p-type impurities are distributed at a low concentration is formed at a position adjacent to the main region 150 in the lateral direction perpendicular to the implantation direction. The peripheral region 158 is defined by the p-type impurities scattered and reflected by the mask 70.

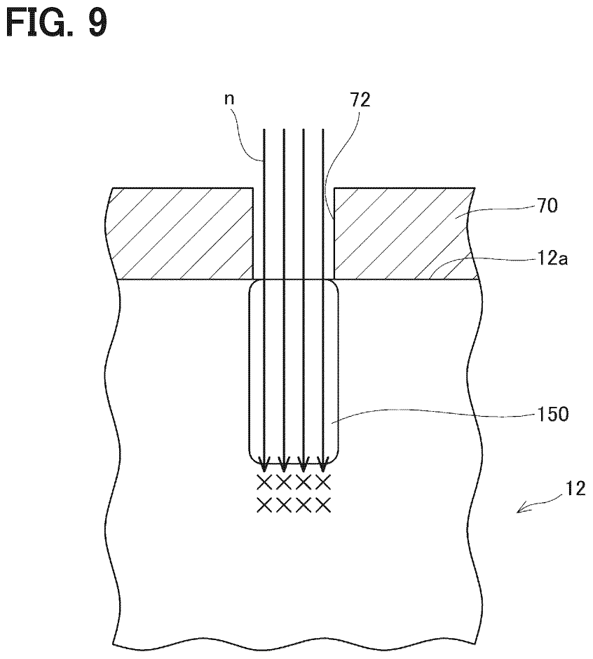

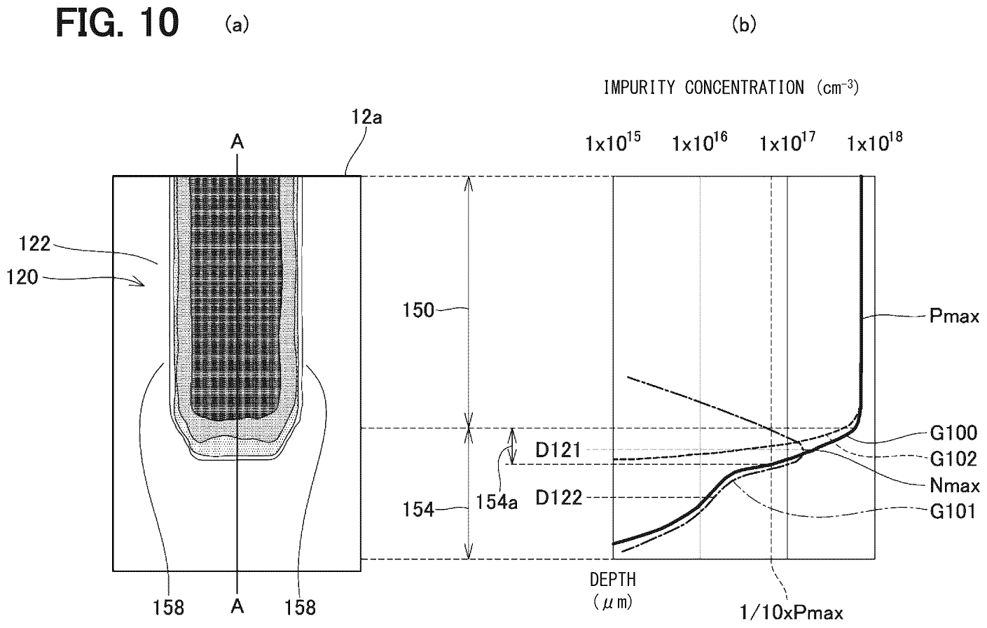

After the first step, the second step is carried out. In the second step, n-type impurity ions are implanted into the SiC substrate 12 through the mask 70. The implantation depth and implantation concentration of the n-type impurity in the second step are set in accordance with the p-type impurity concentration distribution formed in the first step. In the second step, as shown in FIG. 9, n-type impurities are implanted multiple times below the main region 150 while changing the acceleration energy. This implants n-type impurities to multiple depths in the region below the main region 150. In FIG. 10, (b) shows a graph G101 of the concentration distribution of the n-type impurity implanted into the SiC substrate 12 in the second process, superimposed on the graph G100. A region 154a in (b) of FIG. 10, in the reduction region 154, has a p-type impurity concentration higher than 10% of the peak value Pmax. In the second process, n-type impurities are implanted at least once to a depth within the region 154a. In (b) of FIG. 10, n-type impurities are implanted into the reduction region 154 at depths D121, D122 including the depth D121 of the region 154a. The closer to the main region 150 the depth is, the higher the concentration of n-type impurities is implanted at the depths D121, D122. That is, the n-type impurity is implanted at a higher concentration at the depth D121 than at the depth D122. Therefore, in the reduction region 154, a peak value Nmax of the n-type impurity is formed at the depth D121. The n-type impurities are implanted so that the n-type impurity concentration is higher than the p-type impurity concentration in the range below the depth D121. Furthermore, when the n-type impurity is implanted in the second step, the n-type impurity is scattered and reflected by the mask 70. The n-type impurities scattered and reflected by the mask 70 are implanted into the peripheral region 158.

As described above, in the second step, n-type impurities are implanted into the reduction region 154 and the peripheral region 158. A graph G102 in (b) of FIG. 10 shows an effective p-type impurity concentration obtained by subtracting the n-type impurity concentration from the p-type impurity concentration. As shown in (b) of FIG. 10, by implanting n-type impurities into the reduction region 154, the effective p-type impurity concentration in the reduction region 154 becomes lower. In FIG. 10, (a) shows the distribution of the effective p-type impurity concentration in the same cross-section as FIG. 9. As shown in (a) of FIG. 10, by implanting n-type impurities into the peripheral region 158, the effective p-type impurity concentration in the peripheral region 158 becomes lower. In the reduction region 154 and the peripheral region 158, except near the main region 150, the concentration of n-type impurities is higher than the concentration of p-type impurities. Therefore, the effective p-type impurity concentration in the main region 50 and its vicinity has a positive value, and the effective p-type impurity concentration in other regions has a negative value.

Next, the SiC substrate 12 is annealed. This activates the p-type impurities and n-type impurities implanted into the SiC substrate 12. A region with a positive effective p-type impurity concentration becomes a p-type region 120, and a region with a negative effective p-type impurity concentration (where the n-type impurity concentration is higher than the p-type impurity concentration) becomes an n-type region 122. That is, the p-type region 120 is formed in the hatched regions in (a) of FIG. 10, and the n-type regions 122 remains in the non-hatched regions in (a) of FIG. 10. As described above, since the effective p-type impurity concentration is a positive value in the main region 150 and its vicinity, a p-type region is formed in the main region 150 and its vicinity. Since at least a part of the region 154a adjacent to main region 150 is an n-type region, the area in which the p-type region is formed can be narrowed. In this manner, according to this manufacturing method, the p-type region 120 can be formed in a region narrower than the region into which the p-type impurity is implanted in the first step.

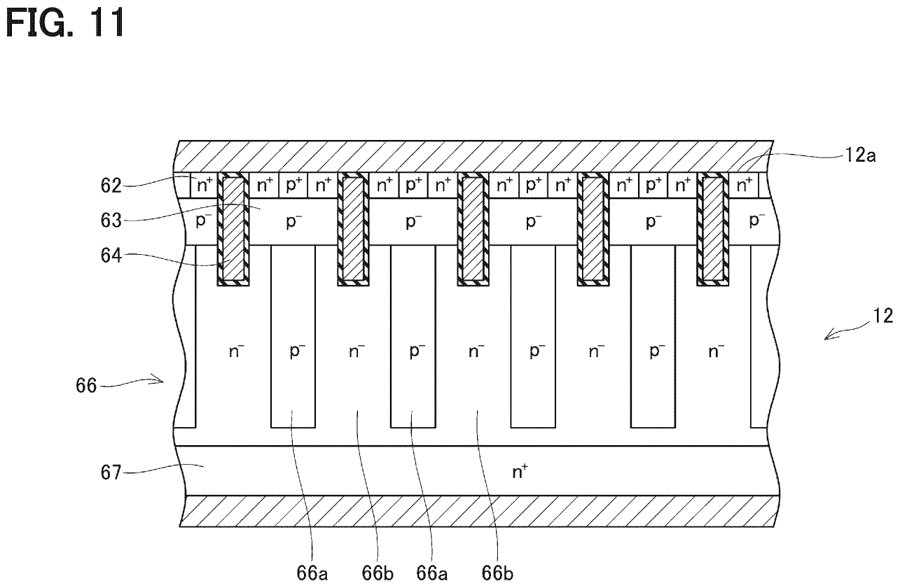

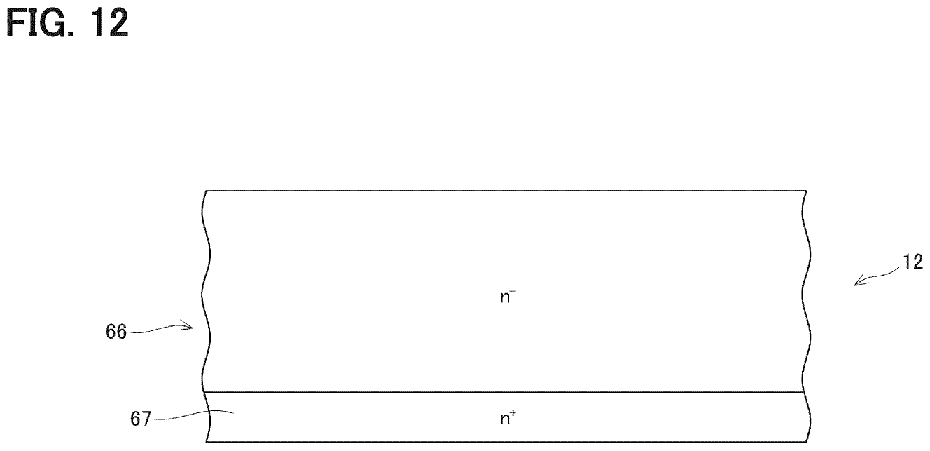

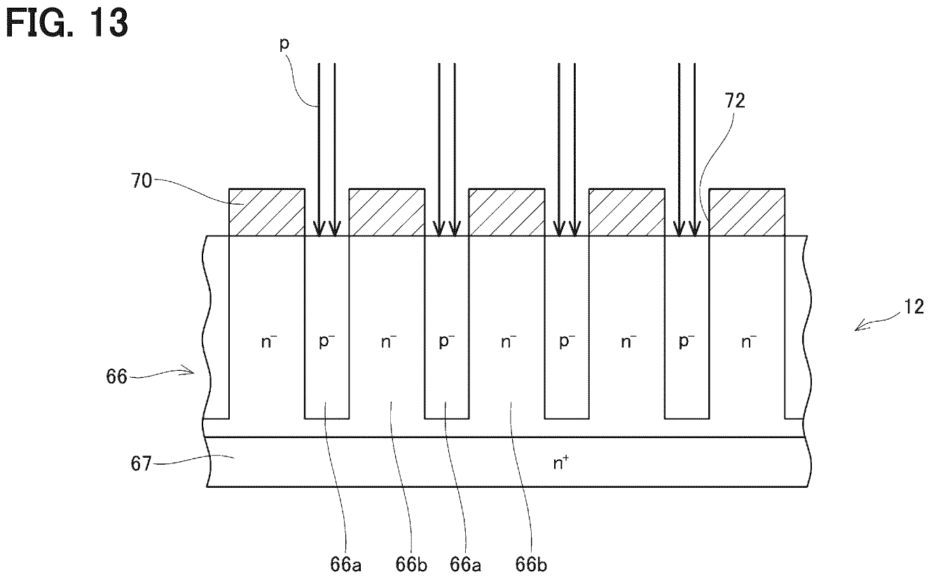

FIG. 11 shows a MOSFET as a specific example of a semiconductor device manufactured by the manufacturing method of the second embodiment. A MOSFET structure having an n-type source region 62, a p-type body region 63, a trench gate electrode 64, a drift region 66, and an n-type drain region 67 is formed in the SiC substrate 12. The drift region 66 has a superjunction structure in which p-type regions 66a and n-type regions 66b are arranged alternately in the lateral direction. Each of the p-type region 66a and the n-type region 66b has a shape that is elongated in the thickness direction of the SiC substrate 12. In this MOSFET manufacturing method, first, as shown in FIG. 12, the drift region 66 is formed on the drain region 67 by epitaxial growth. At this stage, the entire drift region 66 is composed of a low-concentration n-type region. Next, as shown in FIG. 13, a mask 70 is formed on the upper surface of the drift region 66, and impurities are injected through the mask 70 to form plural p-type regions 66a. At this time, by applying the technique of the second embodiment, the range in which the p-type region 66a is formed can be accurately controlled. The n-type region remaining between the p-type regions 66a becomes the n-type region 66b. Thereafter, an epitaxial layer is formed on the drift region 66, and the source region 31, the body region 32, the trench gate electrode 36, and the like are formed in the epitaxial layer, thereby completing the MOSFET shown in FIG. 11.

In the second embodiment, the impurity implantation in the first and second steps is carried out through the mask 70. However, the first and second impurity implants may be performed without the mask. Even with this configuration, a small p-type region can be formed by implanting n-type impurities into the reduction region 154. However, when the p-type impurity is implanted through a mask, the p-type impurity is implanted into the peripheral region 158. When the width of the opening in the mask is 3.5 μm or less, the impurities implanted into the peripheral region 158 becomes more pronounced. Therefore, by using the technique disclosed in this specification when the width of the mask opening is 3.5 μm or less, a greater effect in suppressing the expansion of the p-type region can be obtained.

In the first and second embodiments, p-type impurity ions are implanted in the first step, and n-type impurity ions are implanted in the second step. However, n-type impurities may be ion-implanted in the first step, and p-type impurities may be ion-implanted in the second step.

In the first and second embodiments, the second step is carried out after the first step. However, the first step may be carried out after the second step.

Although the embodiments have been described in detail above, these are merely examples and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A method of manufacturing a semiconductor device comprising:
implanting a first conductivity type impurity into a SiC substrate; and
implanting a second conductivity type impurity into the SiC substrate, wherein
the implanting of the first conductivity type impurity and the implanting of the second conductivity type impurity are conducted to satisfy following conditions:
(i) a concentration distribution of the first conductivity type impurity implanted in a thickness direction of the SiC substrate has a first peak value which is a maximum value, and a reduction region in which a concentration of the first conductivity type impurity continuously decreases with increasing distance from a position of the first peak value;
(ii) a concentration distribution of the second conductivity type impurity implanted in the thickness direction of the SiC substrate has a second peak value which is a maximum value;
(iii) a position of the second peak value overlaps with a specific region of the reduction region having a first conductivity type impurity concentration of 10% or more of the first peak value;
(iv) a position of the first peak value is a first conductivity type region; and
(v) at least a part of the specific region is a second conductivity type region, and
a position of the second peak value overlaps with the specific region located deeper than a position of the first peak value.

2. A method of manufacturing a semiconductor device comprising:
implanting a first conductivity type impurity into a SiC substrate; and
implanting a second conductivity type impurity into the SiC substrate, wherein
the implanting of the first conductivity type impurity and the implanting of the second conductivity type impurity are conducted to satisfy following conditions:
(i) a concentration distribution of the first conductivity type impurity implanted in a thickness direction of the SiC substrate has a first peak value which is a maximum value, and a reduction region in which a concentration of the first conductivity type impurity continuously decreases with increasing distance from a position of the first peak value;
(ii) a concentration distribution of the second conductivity type impurity implanted in the thickness direction of the SiC substrate has a second peak value which is a maximum value;
(iii) a position of the second peak value overlaps with a specific region of the reduction region having a first conductivity type impurity concentration of 10% or more of the first peak value;
(iv) a position of the first peak value is a first conductivity type region; and
(v) at least a part of the specific region is a second conductivity type region,
the semiconductor device manufactured by the method has an element region and a p-type guard ring extending to surround a periphery of the element region, and
the first conductivity type region formed at the position of the first peak value is the guard ring.

3. A method of manufacturing a semiconductor device comprising:
implanting a first conductivity type impurity into a SiC substrate; and
implanting a second conductivity type impurity into the SiC substrate, wherein
the implanting of the first conductivity type impurity and the implanting of the second conductivity type impurity are conducted to satisfy following conditions:
(i) a concentration distribution of the first conductivity type impurity implanted in a thickness direction of the SiC substrate has a first peak value which is a maximum value, and a reduction region in which a concentration of the first conductivity type impurity continuously decreases with increasing distance from a position of the first peak value;
(ii) a concentration distribution of the second conductivity type impurity implanted in the thickness direction of the SiC substrate has a second peak value which is a maximum value;
(iii) a position of the second peak value overlaps with a specific region of the reduction region having a first conductivity type impurity concentration of 10% or more of the first peak value;
(iv) a position of the first peak value is a first conductivity type region; and
(v) at least a part of the specific region is a second conductivity type region,
the semiconductor device manufactured by the method has a superjunction structure in which a plurality of p-type layers and a plurality of n-type layers are alternately arranged in a lateral direction in a drift region, and
the first conductivity type region formed at the position of the first peak value is the p-type layer of the superjunction structure.
